(19) United States
(12) Patent Application Publication
(10) Pub. No.: US 2026/0351961 A1
(43) Pub. Date: Nov. 5, 2026

(54) POWER SUPPLY DEVICE

(71) Applicant: DENSO CORPORATION, Kariya-city, Aichi-pref. (JP)

(72) Inventor: Naoto YOKOYAMA, Kariya-city (JP)

(21) Appl. No.: 19/743,677

(22) Filed: Jul. 16, 2026

Related U.S. Application Data
(63) Continuation of application No. 19/426,985, filed on Dec. 19, 2025.
Application No. 19/426,985 is a continuation of application No. PCT/JP2024/020200, filed on Jun. 3, 2024.

(30) Foreign Application Priority Data
Jun. 29, 2023 (JP) 2023-107121

(51) Int. Cl. H02H 9/02; G01R 19/00; G01R 19/165

(52) U.S. Cl. CPC H02H 9/025; G01R 19/0092; G01R 19/16528

(57) ABSTRACT

A power supply device includes: a power device that supplies current from a driving power source to a load; an off-chip detection resistor through which another current based on the current is energized; a data converter that converts a voltage converted by the off-chip detection resistor into a data value based on a predetermined characteristic; a protection operation unit that performs a protection operation to stop the power device from supplying the current to the load when a calculation value based on the data value exceeds a threshold value; and an IC chip on which the data converter and the protection operation unit are mounted. The IC chip has a configuration capable of switching a voltage level obtained with respect to another current based on the current in a plurality of stages.

### CROSS REFERENCE TO RELATED APPLICATION

This application is a continuation application of U.S. application Ser. No. 19/426,985, filed Dec. 19, 2025, which is a continuation application of International Patent Application No. PCT/JP2024/020200 filed on Jun. 3, 2024, which designated the U.S. and claims the benefit of priority from Japanese Patent Application No. 2023-107121 filed on Jun. 29, 2023. The entire disclosures of all of the above applications are incorporated herein by reference.

### TECHNICAL FIELD

The present disclosure relates to a power supply device including a power device that supplies a current from a driving power source to a load.

### BACKGROUND

For example, a conceivable technique teaches a method of implementing a fuse function using a semiconductor switch to protect a wire harness and a load. Hereinafter, such a protection function may be referred to as eFuse control. To achieve the eFuse control, it is necessary to cut off the current quickly when a large current flows due to the thermal time constant of the wire harness. On the other hand, in order to reduce costs by making the harness thinner, it is necessary to improve the accuracy of current detection near the limit current that can be steadily passed through the harness.

### SUMMARY

According to an example, a power supply device may include: a power device that supplies current from a driving power source to a load; an off-chip detection resistor through which another current based on the current is energized; a data converter that converts a voltage converted by the off-chip detection resistor into a data value based on a predetermined characteristic; a protection operation unit that performs a protection operation to stop the power device from supplying the current to the load when a calculation value based on the data value exceeds a threshold value; and an IC chip on which the data converter and the protection operation unit are mounted. The IC chip has a configuration capable of switching a voltage level obtained with respect to another current based on the current in a plurality of stages.

### BRIEF DESCRIPTION OF THE DRAWINGS

The above and other features and advantages of the present disclosure will become more apparent from the following detailed description made with reference to the accompanying drawings. In the drawing:

FIG. 1 is a diagram showing a configuration of a power supply device according to a first embodiment;

FIG. 2 is a diagram showing the relationship between a load current and an A/D conversion value when the resistance value of an I/V conversion resistor is only a low resistance;

FIG. 3 is a diagram showing the relationship between a load current and an A/D conversion value when the resistance value of an I/V conversion resistor is capable of switching between a low resistance and a high resistance;

FIG. 4 is a diagram (first part) showing a configuration of a gain switching unit;

FIG. 5 is a diagram (second part) showing a configuration of a gain switching unit;

FIG. 6 is a diagram (third part) showing a configuration of a gain switching unit;

FIG. 7 is a diagram showing the relationship between a load current and an A/D conversion value when the gain is switched;

FIG. 8 is a flowchart illustrating a procedure of a process in a control unit according to a second embodiment;

FIG. 9 is a diagram (first part) showing a configuration of a power supply device according to a third embodiment;

FIG. 10 is a diagram (second part) showing a configuration of a power supply device;

FIG. 11 is a diagram showing a configuration of a power supply device according to a fourth embodiment;

FIG. 12 is a flowchart illustrating a procedure of a process in a control unit according to a fifth embodiment, a twelfth embodiment or a thirteenth embodiment;

FIG. 13 is a flowchart illustrating a procedure of a process in a control unit according to a sixth embodiment or a fourteenth embodiment;

FIG. 14 is a diagram showing an example of a table used to determine the type of IPD;

FIG. 15 is a flowchart illustrating a procedure of a process in a control unit according to a seventh embodiment or a fifteenth embodiment;

FIG. 16 is a diagram for explaining a process of correcting an A/D conversion result by applying a linear function;

FIG. 17 is a diagram showing a configuration of a power supply device according to an eighth embodiment;

FIG. 18 is a flowchart showing a procedure of a process in a control unit;

FIG. 19 is a diagram showing a configuration of a power supply device according to an ninth embodiment;

FIG. 20 is a diagram showing a combined resistance value in the chip given according to the on/off states of the switches SW1 to SW4;

FIG. 21 is a diagram showing a relationship between a load current and an A/D conversion value when a combined resistance value of an off-chip detection resistor and an on-chip detection resistor is switched;

FIG. 22 is a diagram showing a configuration of a power supply device according to a tenth embodiment;

FIG. 23 is a diagram showing a combined resistance value in the chip given according to the on/off states of the switches sw1 to sw4;

FIG. 24 is a flowchart illustrating a procedure of a process in a control unit according to an eleventh embodiment;

FIG. 25 is a diagram showing a relationship between a load current and an A/D conversion value when a combined resistance value of an off-chip detection resistor and an on-chip detection resistor is switched;

FIG. 26 is a diagram (first part) showing a configuration of a power supply device according to a twelfth embodiment;

FIG. 27 is a diagram (second part) showing a configuration of a power supply device;

FIG. 28 is a diagram (third part) showing a configuration of a power supply device;

FIG. 29 is a diagram (first part) showing a configuration of a power supply device according to a thirteenth embodiment;

FIG. 30 is a diagram (second part) showing a configuration of a power supply device;

FIG. 31 is a diagram (first part) showing a configuration of a power supply device according to a sixteenth embodiment; and

FIG. 32 is a diagram (second part) showing a configuration of a power supply device;

### DETAILED DESCRIPTION

There is a method in which two types of resistors for I/V conversion are prepared with respect to an output for monitoring a current flowing through a semiconductor switch, and are switched according to the current range. In this case, in the current range where measurement is required by switching from high resistance to low resistance, the current measurement resolution decreases, and it becomes necessary to perform protection operation by cutting off the fuse earlier than the ideal fusing characteristic. Furthermore, on the high resistance side, it is necessary to select a resistance value that ensures current detection accuracy near the current that can be steadily flowed through the harness, and due to a decrease in measurement resolution in the small load current range and A/D conversion errors, it is difficult to determine whether the load has a good condition or a bad condition and to grasp the load state such as a wake-up/sleep state. As a countermeasure, increasing the number of resistance values increases the cost.

The present disclosure has been made in consideration of the above circumstances, and has an object to provide a power supply device that can improve the resolution of current detection while suppressing an increase in costs.

According to the power supply device of the present disclosure, when a current is supplied from a driving power source to a load via a power device, a current based on that current is energized through an off-chip detection resistor and converted into a voltage. Here, a power device is a semiconductor element that constitutes a power conversion circuit such as an inverter and is capable of switching a relatively large amount of power. The data converter converts the voltage converted by the off-chip detection resistor into a data value based on a predetermined characteristic.

When a calculation value based on the data value exceeds a threshold value, the protection operation unit performs a protection operation to stop the power device from supplying the current to the load. The data converter and the protection operation unit are mounted on an IC chip, and the IC chip has a configuration capable of switching the voltage level obtained in multiple stages with respect to a current based on the current.

In order to be able to detect the current even when the maximum load current flows, it is necessary to switch the voltage level so that the I/V conversion voltage becomes the maximum input voltage of the data converter. The resistors used within the chip to realize a configuration capable of switching the voltage level in multiple stages are each configured to have a resistance value by arranging reference resistors. Therefore, although variations in the absolute resistance values occur due to variations in the semiconductor manufacturing process, it is possible to reduce the variations in the resistance ratio, and it is possible to switch the voltage level with high accuracy.

Furthermore, according to the power supply device of the present disclosure, the gain switching unit switches the voltage level obtained by switching the gain for a current based on the current. The data converter performs data conversion with the gain set to the minimum, and the gain for detecting the current is determined according to the converted data value. With this configuration, an appropriate gain can be selected, and the current being energized through the load can be detected by performing data conversion at most twice.

Furthermore, according to the power supply device of the present disclosure, when the power device stops energizing the load, an anomaly in the connection state of the off-chip detection resistor can be determined based on the data value converted when the source side current supply unit energizes the off-chip detection resistor.

### First Embodiment

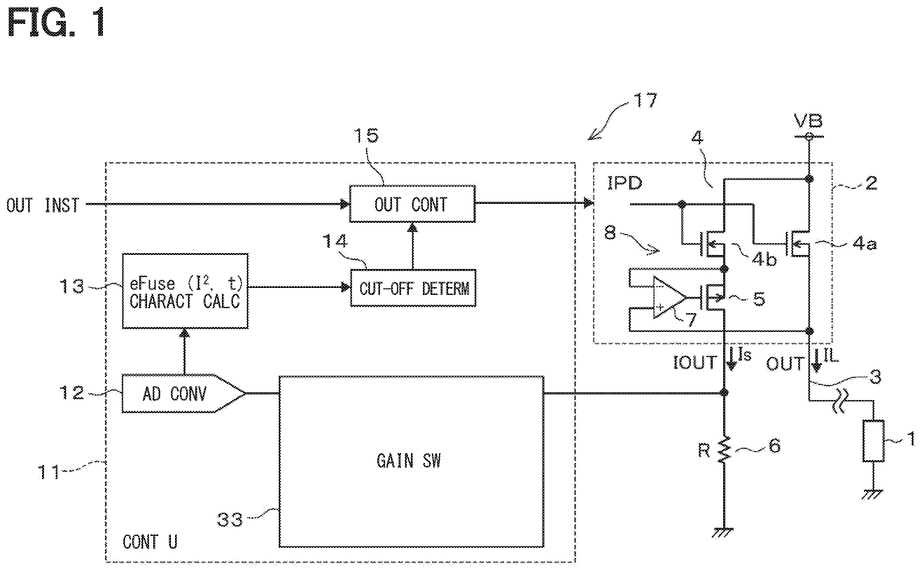

As shown in FIG. 1, the power supply device of this embodiment energizes from a power source VB through an IPD 2 and a harness 3 to a load 1 having one end connected to the ground. The IPD 2 includes N-channel MOSFETs 4a and 4b whose drains are connected to a power supply VB and whose gates are commonly connected. The source of the FET 4a, which is an example of a power device, is connected to the load 1 via the harness 3, and the source of the FET 4b is connected to the ground via a P-channel MOSFET 5 and an off-chip detection resistor having a resistance value R. Hereinafter, this will be referred to as an off-chip detection resistor R.

The source of the FET 4b, together with the source of the FET 5, is connected to the inversion input terminal of an operational amplifier 7, the non-inversion input terminal of the operational amplifier 7 is connected to the source of the FET 4a. The FETs 4a and 4b form a transistor pair 4. The FET 4b is a so-called sense MOS, and the FETs 4b and 5 and the operational amplifier 7 constitute a current output circuit 8. The gate of the transistor pair 4 is driven by the control unit 9.

Inside the control unit 11 configured by an IC, an A/D converter 12, an eFuse (I², t) characteristic calculation unit 13, a cut-off determination unit 14, and an output control unit 15 are serially connected. An input terminal of an A/D converter 12, which is an example of a data converter, is connected to a common connection point of the IPD 2 and the off-chip detection resistor 6. The data converted by the A/D converter 12 is input to an eFuse (I², t) characteristic calculation unit 13. The result of the calculation by the calculation unit 13 is input to the cut-off determination unit 14, and the determination result of the cut-off determination unit 14 is input to the output control unit 15.

The eFuse (I²,t) characteristic calculation unit 13 calculates and outputs the data converted by the A/D converter 12 based on data proportional to the square of the detected current, for example, as the “multiplication circuit 200” shown in FIG. 1 of JP 2023-18957 A. Here, the disclosure in JP 2023-18957 A is incorporated herein by reference. This is based on the feature that the smoke generation time t of the harness 3 has a characteristic that depends on the square of the current to be energized, as described in the publication of JP 2023-18957 A.

The cut-off determination unit 14 compares the data calculated as above with a threshold value to determine whether or not to issue a cut-off instruction. The output control unit 15 drives the gates of the transistor pair 4 of the IPD 2 in response to an output instruction input from a higher-level control device (not shown). Furthermore, when a cut-off instruction is input from the cut-off determination unit 14, the output control unit 15, which corresponds to a protection operation unit, turns off the transistor pair 4.

A gain switching unit 33 is connected between the input terminal of the A/D converter 12 and the off-chip detection resistor 6. The gain switching unit 33 allows the gain to be switched between two or more stages. The gain switching control is performed by the eFuse (I², t) characteristic calculation unit 13. The components other than the harness 3 and the load 1 constitute the power supply device 17.

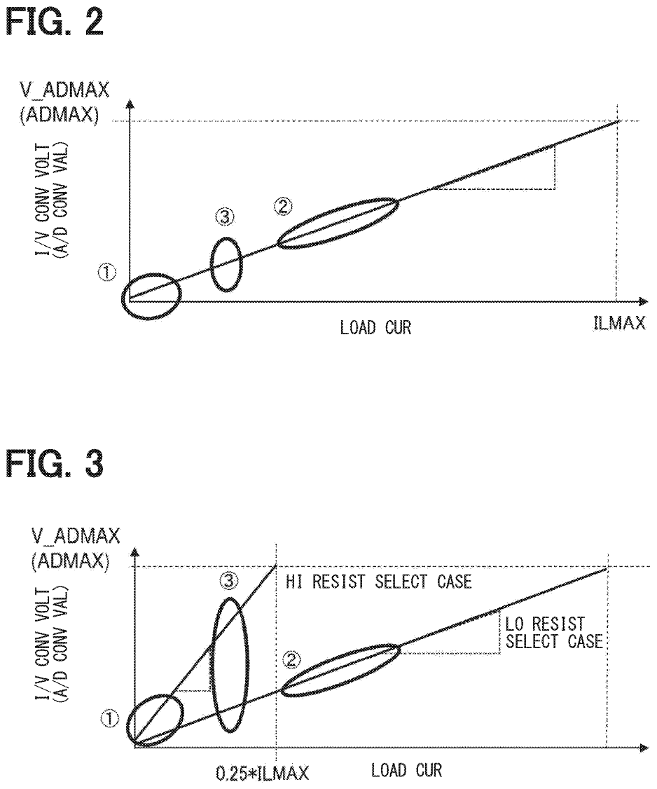

Next, the operation of the present embodiment will be described. As shown in FIG. 2, in the load current to I/V conversion characteristics when a low gain is selected, in the region (1) where the load current value is small, there is also the influence of errors due to A/D conversion, it is difficult to determine whether the load is a good condition or a bad condition and whether the load is in a wake-up state or a sleep state. The numbers in parentheses correspond to the circled numbers in the drawings. In the region (2), since the measurement resolution of the current is low, it becomes necessary to perform a protection operation such that the IPD 2 is cut off at a time earlier than the ideal fusing characteristic of the harness 3. The region (3) shows the current value that can be steadily passed through the harness 3.

If the characteristics when a high gain is selected are considered to FIG. 2, the result is as shown in FIG. 3. In this way, it is necessary to select the gain so as to ensure the current detection accuracy in the vicinity of the region (3).

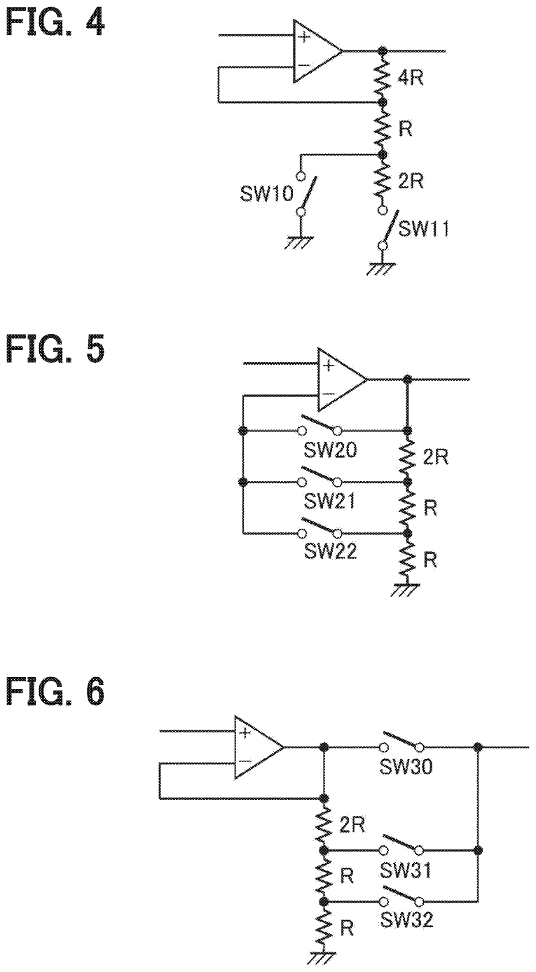

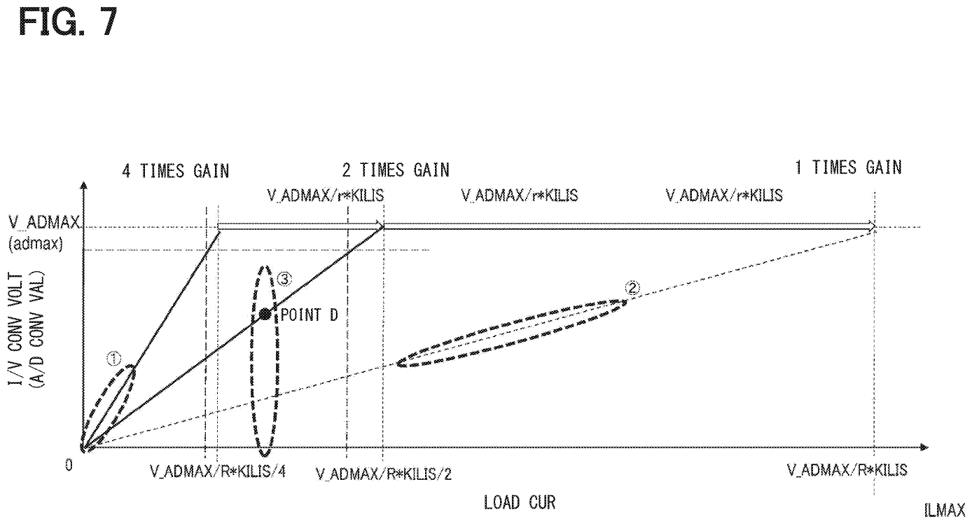

The gain switching unit 33 can be configured with a circuit as shown in FIG. 4 or 5. By changing the on/off combinations of the switches SW10 to SW11 or by selectively turning on the switches SW20 to SW22, the gain can be changed to one time, two times, or four times. This gain switching results in a load current to I/V conversion characteristic as shown in FIG. 7. Here, the load current is defined as IL, the monitor current flowing to the off-chip detection resistor 6 side is defined as IS, the resistance value of the off-chip detection resistor 6 is defined as R, the current ratio is defined as KILIS, and the maximum input voltage of the A/D converter 12 is defined as V_ADMAX. When the gain is one time, it is possible to detect a current up to a value of “V_ADMAX/R×KILIS”. When the gain is two times, it is possible to detect a current up to a value of “V_ADMAX/R×KILIS/2”. When the gain is four times, it is possible to detect a current up to a value of “V_ADMAX/R×KILIS/4”.

The gain switching unit 33 can also be configured with a circuit as shown in FIG. 6, and the output voltage can be changed to ¼ times, ½ times, or one time by selectively turning on the switches SW30 to SW32. If the lowest output voltage is used as a reference, the gain can be changed to one time, two times, or four times in the same way.

In order to be able to detect the current even when the maximum load current ILMAX flows, it is necessary to set the lowest gain so that the I/V conversion voltage is equal to or lower than the maximum input voltage V_ADMAX of the A/D converter 12.

If it is assumed that the configuration of this embodiment is applied to, for example, an ECU (i.e., Electronic Control Unit), in order to improve the detection accuracy, it is necessary to pass a load current when correcting the characteristics of the IPD 2 and the off-chip detection resistor 6 during the manufacturing process. In this case, correction is performed within the constraints of the inspection jig and devices, and using a current value that provides sufficient A/D conversion accuracy, and using a gain setting by the gain switching unit 33 to ensure the highest resolution under at least one condition, preferably at point D (see FIG. 7) near the upper limit current (3) that can be steadily passed through the harness, where the highest current accuracy is required. When other gain switching settings are used, the ECU inspection time can be reduced by performing correction based on the gain ratio.

Here, when the gain switching unit 33 switches the gain to one time, two times, or four times, if it is desired to obtain the characteristics of a square of the current, the gain becomes one time, four times, or sixteen times with respect to the input. The four times and sixteen times magnifications can be achieved by a two-bit shift and four-bit shift of the digital data, respectively, and can be configured with simple arithmetic circuits. The gain may be switched between one time, square root of 2 times, two times, and so on. Similarly, when it is desired to obtain a squared current characteristic, the gain for the switching settings becomes one time, two times, or four times with respect to the input. The two times and four times magnifications can be achieved by a one-bit shift and two-bit shift of the digital data, respectively, and can be configured with simple arithmetic circuits.

Furthermore, taking into consideration the gain error of the gain switching unit 33, the lower the gain, for example, to set the gain to be “((4/2)+α)/2+β” times, “(4/2)+α” times, or four times, the slightly higher the gain is set, so that, in a region where the load current is large, a data conversion result corresponding to a larger current value can be obtained when the gain is switched to the lower level. As the calculation value based on that data value increases more quickly, the calculation value is more likely to exceed the threshold value sooner, so that it is possible to take a protection operation for stopping the current supply to the load by the power device more quickly. Therefore, even if there is variation in the quality of the gain of the gain switching unit 33, the protection operation can be achieved more safely.

As described above, according to this embodiment, when a current is supplied from the drive power source VB to the load 1 via the FET 4a and the harness 3, a current based on that current is energized through the off-chip detection resistor 6 to be converted into a voltage. The gain switching unit 33 selects a gain that can ensure the highest resolution within the range of voltages that can be input to the A/D converter 12 at the subsequent stage. Thus, it is possible to virtually improve the resolution of the data conversion in the A/D converter 12. Further, it is possible to improve the accuracy of current detection in the small current region where the accuracy is most required and in the vicinity of the upper limit current that can steadily flow through the harness 3.

### Second Embodiment

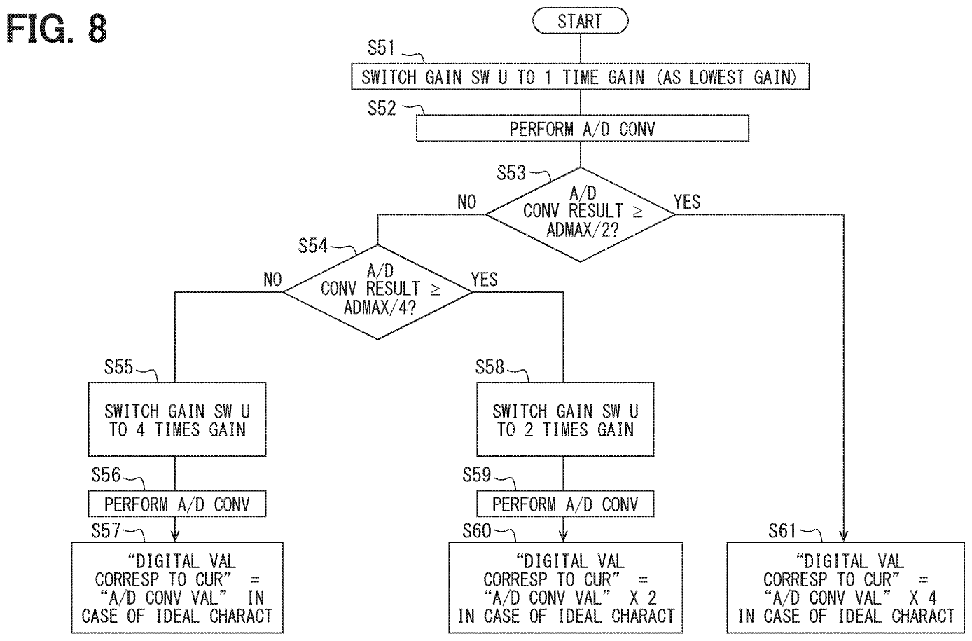

Hereinafter, the identical parts as those in the first embodiment will be designated by the same reference numerals for simplification of the description. Only differences from the first embodiment will be described below. As shown in FIG. 8, the second embodiment shows the control contents in the control unit 11. When the process starts, the gain of the gain switching unit is set to the lowest value of 1 (at S51), and the A/D conversion is performed (at S52). This process corresponds to the first data conversion. Then, when the maximum output value of the A/D conversion circuit is set as “admax”, it is determined whether the A/D conversion result is equal to or greater than a value of “admax/2” (at S53).

If the A/D conversion result is equal to or greater than the conversion value of “admax/2” (“YES” at S53), a value obtained by multiplying the A/D conversion result by four times is defined as the final digital value according to the detected current (at S61). Here, in the “ideal characteristic case” shown in the drawings, in order to simplify the explanation, the case where the conversion characteristic of the current output circuit 8 becomes nonlinear in the low current region is actually ignored.

If the A/D conversion result is less than the conversion value of “admax/4” (“NO” at S54), the gain of the gain switching unit is switched to a gain of four times (at S55), and the A/D conversion is performed in the same manner as in step S2 (at S56). Then, the A/D conversion result is directly used as the final digital value (at S57). If the A/D conversion result is less than the conversion value of “admax/2” and greater than or equal to the conversion value of “admax/4” (“YES” at S54), the gain of the gain switching unit is switched to a gain of two times (at S58) and the A/D conversion is performed (at S59). Then, the A/D converted result is doubled to obtain the final digital value corresponding to the detected current (at S60).

The conversion values between “admax/2” and “admax/4” may be finely adjusted according to the characteristics of the gain switching circuit in the chip, or may be stored in advance in a storage unit 11M (not shown) provided in the control unit 11.

As described above, according to the second embodiment, the conversion resolution in the current regions (1) and (3) can be improved by performing the A/D conversion a maximum of two times.

### Third Embodiment

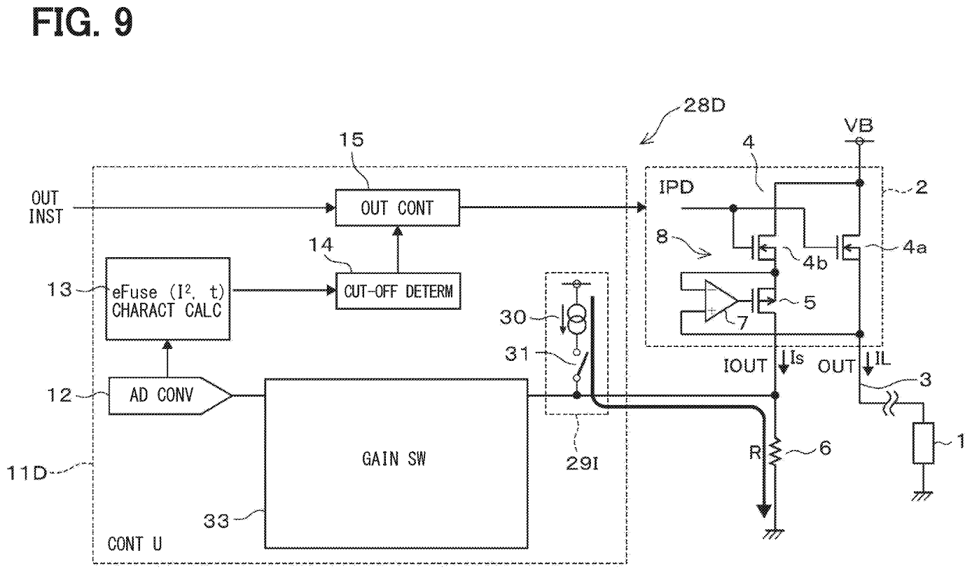

As shown in FIG. 9, a power supply device 28D of the third embodiment includes a source-side current supply unit 29I in a control unit 11D. The source side current supply unit 29I is configured with a series circuit of a current source 30 and a switch 31 connected between the source side current supply unit 29I and an internal power supply.

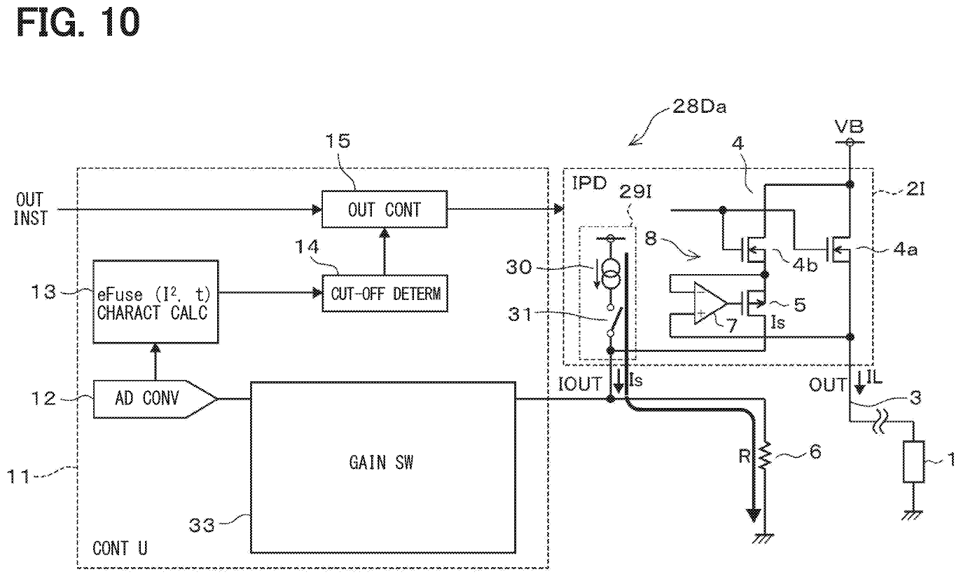

In addition, in a power supply device 28Da shown in FIG. 10, a source-side current supply unit 29I is disposed inside the IPD 2I. The source side current supply unit 29I here is for diagnostics within the chip of the IPD2I.

In the configuration shown in FIGS. 9 and 10, when the load 1 is not energized from the IPD 2 or 2I, a current Itest is supplied from the source side current supply unit 29I to the off-chip detection resistor 6, and the resulting voltage V_val1 is detected by the A/D converter 12. Similarly, when the load 1 is not energized from the IPD 2 or 2I, a current is supplied from the source side current supply unit 29I to the off-chip detection resistor 6, and the resulting voltage V_val2 is detected by the A/D converter 12.

In the case of the configuration shown in FIG. 9, the voltage V_val1 generated when the gain of the gain switching unit 33 is set to one is expressed as an expression of “V_val1=R×Itest”.

In the configuration shown in FIG. 10, when the load 1 is not energized from the IPD 2I and the gain of the gain switching unit 33 is set to a gain of one, if a current Idiag is supplied from the source side current supply unit 29I, the resulting voltage V_val1 is expressed as an expression of “V_val1=R×Idiag”.

By comparing the value of V_val1 or V_val2 with the expected value under normal conditions, it is determined whether there is an anomaly in the connection state of the off-chip detection resistor 6, and determined the type of resistance value of the off-chip detection resistor 6, thereby, it is possible to set various control parameters, which will be described later, without using a microcomputer or the like to set the various control parameters.

### Fourth Embodiment

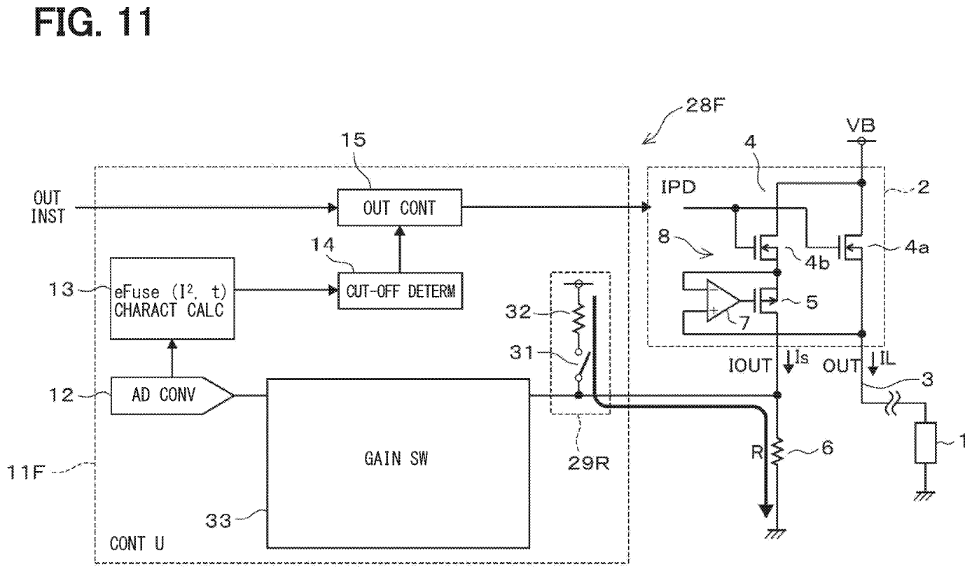

A power supply device 28F of the fourth embodiment shown in FIG. 11 includes a source-side current supply unit 29R in a control unit 11F. The source side current supply unit 29R includes a resistive element 32 having a resistance value Rtest instead of the current source 30.

In the case of the configuration shown in FIG. 11, when the load 1 is not energized from the IPD 2 and the gain of the gain switching unit is set to a gain of one, when the switch 31 of the source side current supply unit 29R is turned on, the generated voltage V_val1 is expressed as an expression of “V_val1=VCC×R/(R+Rtest)”.

### Fifth Embodiment

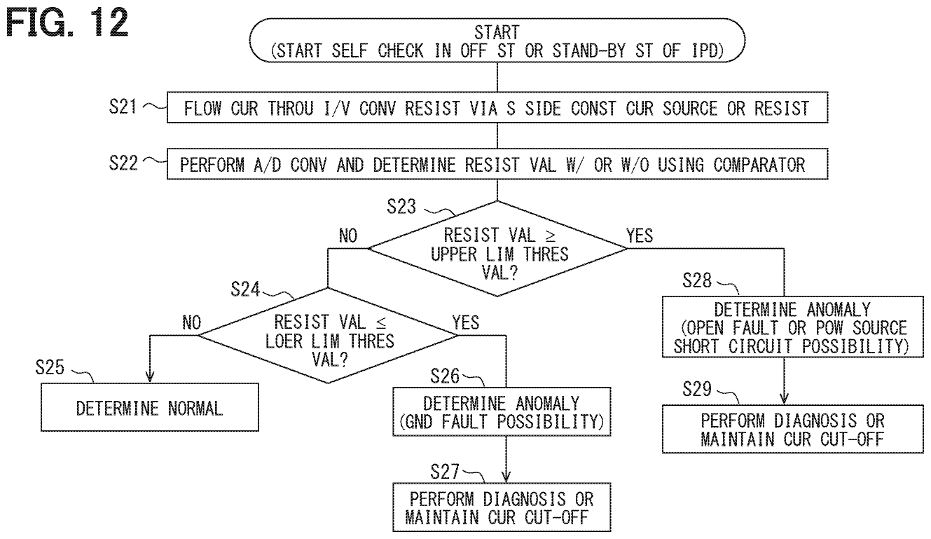

FIG. 12 shows the fifth embodiment. The control contents shown in FIG. 12 can be similarly applied to the configuration of the fourth embodiment. As shown in the drawings, the process starts in a self-check mode with the output control unit 15 turning off the IPD 2 or controlling the IPD 2 in a standby mode. First, the switch 31 of the source side current supply unit 29I or 29R is turned on to pass a current through a resistor for I/V conversion, i.e., the off-chip detection resistor 6 (at S21). Then, the A/D conversion is performed by the A/D converter 12, and the resistance value that can be read from the conversion result is determined (at S22). Here, a comparator may be used for the determination.

If the determined resistance value is equal to or greater than the upper threshold value (“YES” at S23), there is a possibility that the connection of the I/V conversion resistor is open or shorted to the power supply, and therefore it is determined that an anomaly has occurred (at S28). Then, for example, an instruction to execute a diagnosis is transmitted to a higher-level control device or the IPD 2 is maintained in the off state (at S29).

If the determined resistance value is equal to or less than the lower threshold value (“YES” at S24), there is a possibility that the connection of the I/V conversion resistor has a ground fault, and therefore it is determined that an anomaly has occurred (at S26). Then, a process similar to that in step S29 is performed (at S27). On the other hand, if the determined resistance value is above the lower threshold value (“NO” at S24), it is determined to be normal (at S25).

As described above, according to the fourth or fifth embodiment, by determining the resistance value when a source current is passed through the I/V conversion resistor via the source side current supply unit 29 while the IPD 2 stops energizing the load 1, it is possible to determine whether the connection of the I/V conversion resistor is normal or anomaly.

### Sixth Embodiment

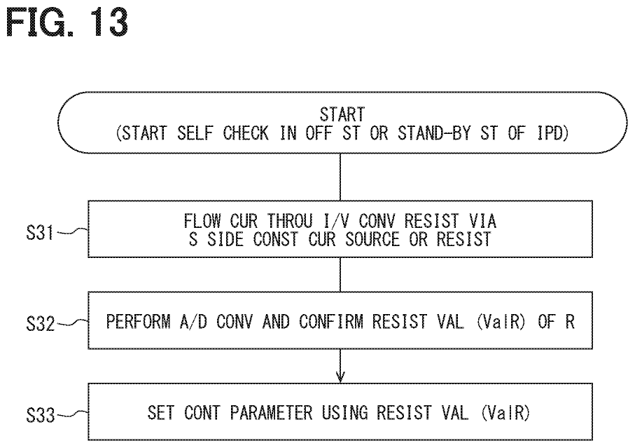

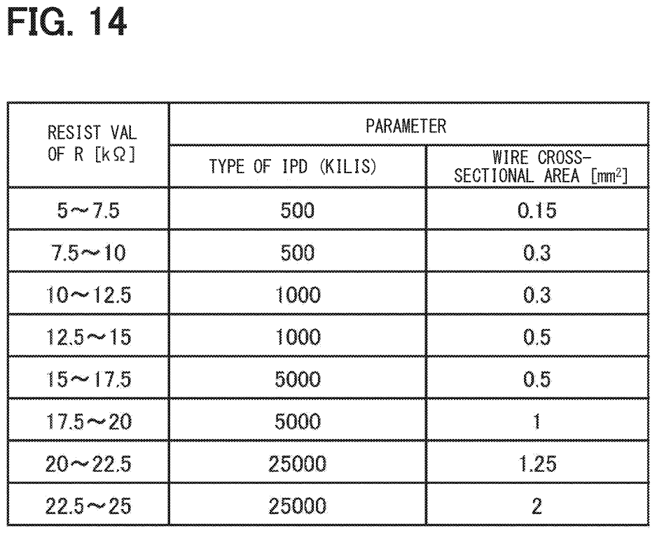

As shown in FIGS. 13 and 14, in the sixth embodiment, the type of the connected IPD 2 is determined based on the resistance value of the off-chip detection resistor 6 in a control unit 11F of the fourth or fifth embodiment. As shown in FIG. 13, when process is started in a self-check mode in the same manner as in the fourth embodiment, the process similar to step S21 is performed (at S31). Then, the A/D conversion is performed by the A/D converter 12, and the conversion result is obtained as resistance value data ValR (at S32). The control parameters are set based on the resistance value data ValR (at S33).

The control unit 11F stores a data table for determining the type of the IPD 2, for example, as shown in FIG. 14. For example, if the resistance value R is in the range of 5 kΩ to 7.5 kΩ, the type of the IPD 2 is defined as “KILIS=500”, and the wire cross-sectional area of the harness 3 is 0.15 mm². For example, if the resistance value R is in the range of 10 kΩ to 12.5 kΩ, the type of the IPD 2 is defined as “KILIS=1000”, and the wire cross-sectional area of the harness 3 is 0.3 mm². These are set as parameters used in eFuse control. This information can also be used to enable the control to be started with rough parameters before obtaining information such as accurate conversion ratios and correction values from a higher level microcomputer, for example.

By providing the gain switching unit 33 inside the chip, there is no difficulty even if the resistance value of the off-chip detection resistor 6 is high. Therefore, parameter setting and current monitoring can be achieved with one terminal, so that it is not necessary to provide a terminal that has conventionally been provided for setting parameters. Thus, it is possible to reduce the number of terminals and components such as resistors dedicated to parameter setting.

### Seventh Embodiment

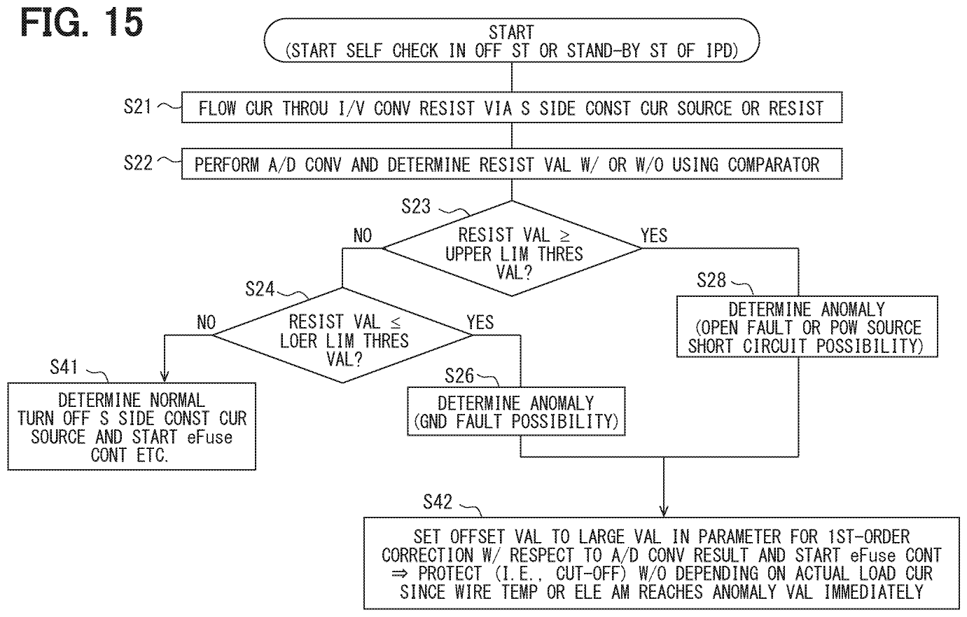

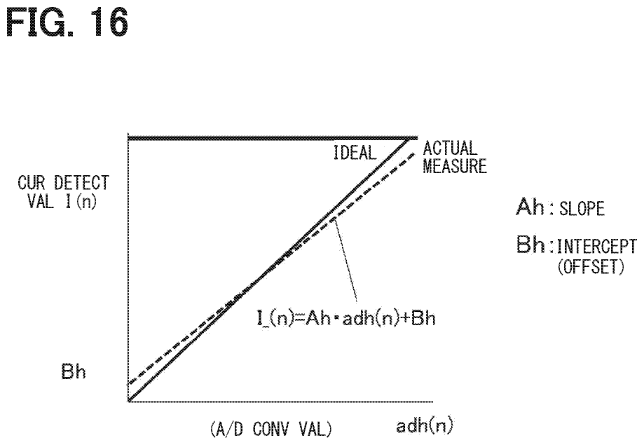

As shown in FIG. 15, in the seventh embodiment, the quality of the connection of the off-chip detection resistor 6 is determined in the same manner as in the fourth embodiment and the like. After steps S26 and S28 have been executed, for example, when performing correction on the A/D conversion result using a linear function, Bh shown in FIG. 16 as an offset parameter, i.e., an intercept, is changed to a value larger than the value normally used (at S42). Here, the functional part that performs the correction using the linear function corresponds to the correction unit.

Thereafter, when the IPD 2 starts energizing, it is possible to recognize using the correction value of the A/D conversion result that a large current is flowing regardless of the actual load current IL. As a result, by the eFuse control function or the power amount monitoring function, the protection to cut off the current is activated in a short time, so that the load 1 can be safely protected. If the determination at step S24 is “No,” the source-side current supply source 29 is turned off and eFuse control and the like are started.

### Eighth Embodiment

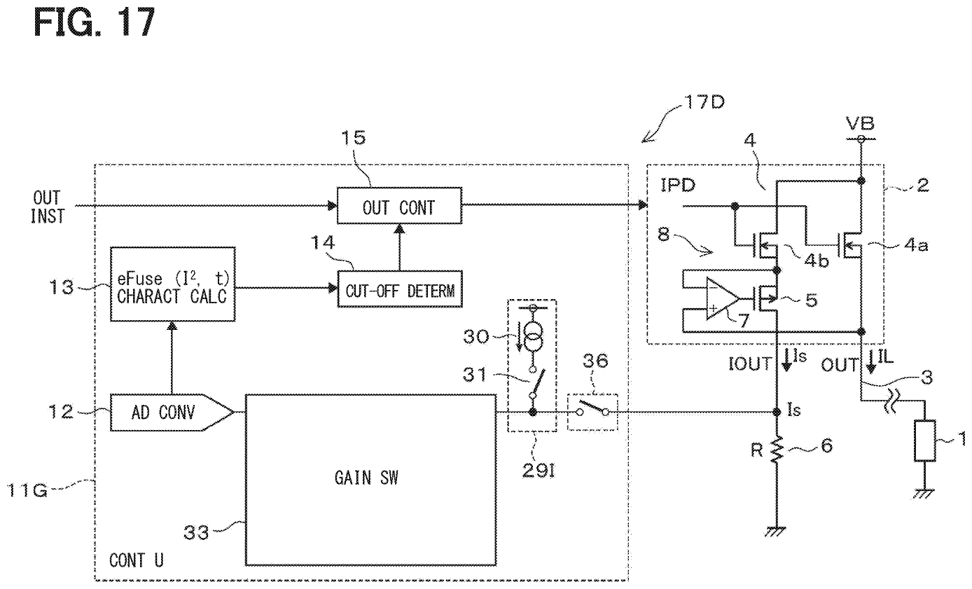

The eighth embodiment is a modification of the seventh embodiment. As shown in FIG. 17, a normally-closed switch 36 is inserted between the off-chip detection resistor 6 and the gain switching unit 33, and the source side current supply unit 29I of the sixth embodiment is connected to the common connection point between the gain switching unit 33 and the switch 36.

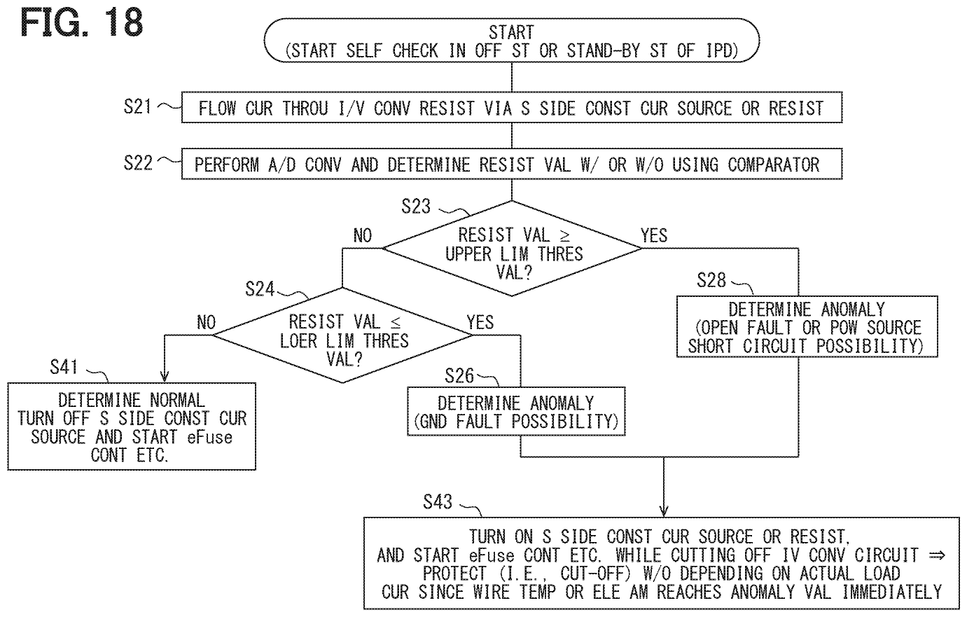

In the flow chart shown in FIG. 18, step S42 is replaced with step S43. In step S43, the switch 36 is turned off, and the switch 31 of the source side current supply unit 29I is turned on. As a result, when the IPD 2 starts energizing, the voltage input to the A/D converter 12 becomes higher than the normal input range, so that it is recognized that a large current is flowing regardless of the actual load current IL. As a result, by the eFuse control function or the power amount monitoring function, the protection to cut off the current is activated in a short time, so that the load 1 can be safely protected.

### Other Embodiments

The change in gain in the gain switching unit 33 may be set in two stages, or three or more stages. Moreover, the A/D converter 12 and the eFuse (I², t) characteristic calculation unit 13 may be integrated to configure a data converter that outputs a conversion result according to the characteristic of the squared current.

### Ninth Embodiment

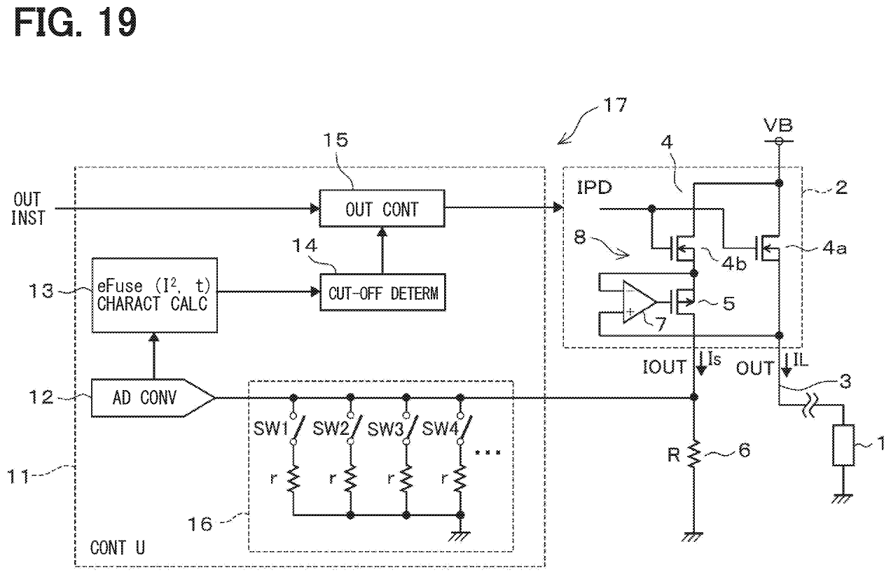

As shown in FIG. 19, in the ninth embodiment, a resistance value changing unit 16 is connected between the input terminal of the A/D converter 12 and the ground. The resistance value changing unit 16 includes a series circuit in which a resistor element having a resistance value of r corresponding to the on-chip detection resistor is connected to each of the switches SW1 to SW4. Hereinafter, this will be referred to as an on-chip detection resistor r. “on-chip” and “off-chip” refer to being inside and outside the IC chip, respectively. It should be noted that five or more pairs of switches and on-chip detection resistors may be provided. The on/off control of the switches S1 to S4 is performed by an eFuse (I², t) characteristic calculation unit 13. The components other than the harness 3 and the load 1 constitute the power supply device 17.

Next, the operation of the ninth embodiment will be described. As shown in FIG. 2, in the load current to I/V conversion characteristics when a resistance value is set to be low, in the region (1) where the load current value is small, there is also the influence of errors due to A/D conversion, it is difficult to determine whether the load is a good condition or a bad condition and whether the load is in a wake-up state or a sleep state. In the region (2), since the measurement resolution of the current is low, it becomes necessary to perform a protection operation such that the IPD 2 is cut off at a time earlier than the ideal fusing characteristic of the harness 3. The region (3) shows the current value that can be steadily passed through the harness 3.

If the characteristics when a resistance value is set to be high are considered with respect to FIG. 2, the result is as shown in FIG. 3. In this way, it is necessary to select a resistance value so that the current detection accuracy in the vicinity of region (3) can be ensured even if the resistance is simply switched to a high resistance.

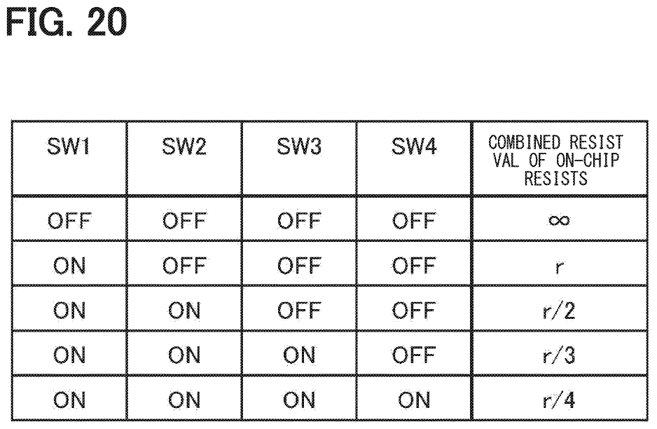

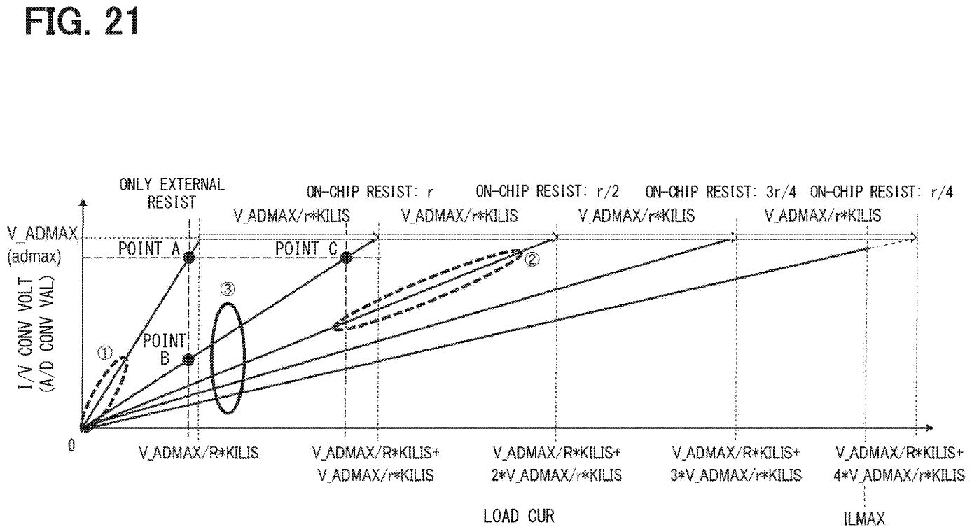

In the ninth embodiment, in the resistance value changing unit 16, as shown in FIG. 20, by selectively turning on switches S1 to S4, the combined resistance value of the on-chip detection resistor r is changed to infinity, r, r/2, r/3, or r/4. By adding a high resistance setting using only the off-chip detection resistor R to a combined resistance value using the on-chip detection resistor r in parallel, the load current to I/V conversion characteristic becomes as shown in FIG. 21.

In order to be able to detect the current even when the maximum load current ILMAX flows,
the resistance values of each resistor are set so that the I/V conversion voltage is equal to or lower than the maximum input voltage V_ADMAX of the A/D converter 12 when all of the on-chip detection resistors r are connected. Moreover, each of the on-chip detection resistors r is configured to have a respective resistance value by arranging reference resistors. Therefore, although variations in the absolute resistance values occur due to variations in the semiconductor manufacturing process, it is possible to reduce the variations in the resistance ratio.

If it is assumed that the configuration of the ninth embodiment is applied to, for example, an ECU (i.e., Electronic Control Unit), in order to improve the detection accuracy, it is necessary to pass a load current when correcting the characteristics of the IPD 2 and the off-chip detection resistor R during the manufacturing process. At this time, the correction is performed under at least two conditions, that is, within the constraints of the inspection jig and device and at the same time, with a current value that provides sufficient A/D conversion accuracy and the setting of the resistance value changing unit 16. When other switching settings are made, the ECU inspection time can be shortened by performing correction based on the resistance ratio.

Here, if the load current is defined as IL, the monitor current flowing through the off-chip detection resistor R is defined as IS, and the current ratio of the off-chip detection resistor R is defined as KILIS, the relationship between the currents IL and IS is expressed as an expression of “IL=KILIS×IS”. For example, as shown in FIG. 21, the on-chip detection resistor r is not connected, and a constant load current IL is passed only through the off-chip detection resistor R. In this case, the value of “R×KILIS” can be corrected by performing the A/D conversion at point A. Furthermore, by connecting only one on-chip detection resistor r in parallel and performing the A/D conversion at point B, it becomes possible to correct the value of r.

As another method, the load current IL is made variable, the current flows only through the off-chip detection resistor R, and the load current that reaches a certain A/D conversion value corresponding to point A is obtained and the value of R is corrected. Furthermore, it is also possible to connect only one on-chip detection resistor r in parallel and correct the value of r by determining the load current that reaches a certain A/D conversion value corresponding to point C.

When detecting the load current IL, the combined resistance value is successively decreased by changing the state of the off-chip detection resistor R from a state where no on-chip detection resistors r are connected to the off-chip detection resistor R to states where one to four on-chip detection resistors r are sequentially connected to the off-chip detection resistor R in parallel. When the on-chip detection resistor r is not connected, the load current IL can only be detected in the range of “IL=0 ”

to “IL=V_ADMAX/(R×KILIS)”.

In the ninth embodiment, in the resistance value changing unit 16, the on-chip detection resistors r are sequentially connected in parallel, so that the load current IL can be detected in the range of “IL=0” to “IL=V_ADMAX/(R×KILIS)+V_ADMAX/(r×KILIS)”, the range of “IL=0” to “IL=V_ADMAX/(R×KILIS)+2 V_ADMAX/(r×KILIS)”, the range of “IL=0” to “IL=V_ADMAX/(R×KILIS)+3 V_ADMAX/(r×KILIS)”, and the range of “IL=0” to “IL=V_ADMAX/(R×KILIS)+4 V_ADMAX/(r×KILIS)”, respectively.

As described in the ninth embodiment, according to this embodiment, when a current is supplied from the drive power source VB to the load 1 via the FET 4a and the harness 3, a current based on that current is energized through the off-chip detection resistor R to be converted into a voltage. The A/D converter 12 converts the voltage converted by the off-chip detection resistor R into a data value. When the calculation value based on the data value exceeds a threshold value, the output control unit 15 performs a protection operation to stop the current supply to the load 1 by the FET 4a. The resistance value changing unit 16 having a plurality of on-chip detection resistors r is mounted on a control unit 11 formed of an IC, and is made connectable in parallel to the off-chip detection resistors 6.

In this way, even if the number of on-chip detection resistors r formed in the control unit 11 constituted by an IC is increased, this does not lead to an increase in costs. By changing the combined resistance value with the off-chip detection resistor R by the resistance value changing unit 16, the voltage input to the A/D converter 12 can be further reduced. Thus, it is possible to virtually improve the resolution of the data conversion in the A/D converter 12. Further, it is possible to improve the accuracy of current detection in the small current region where the accuracy is most required and in the vicinity of the upper limit current that can steadily flow through the harness 3.

### Tenth Embodiment

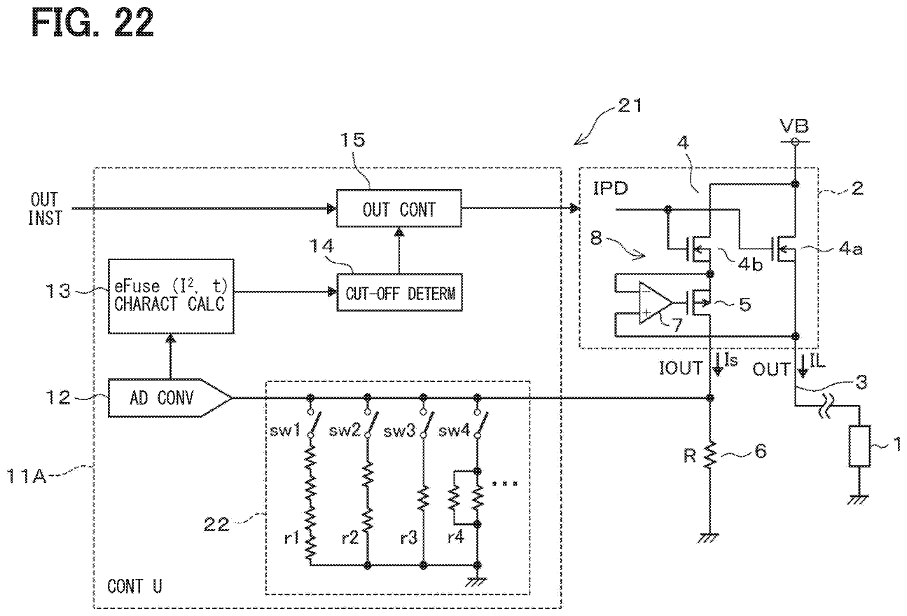

As shown in FIG. 22, a power supply device 21 of the tenth embodiment includes a resistance value changing unit 22 instead of the resistance value changing unit 16. In the resistance value changing unit 22, the on-chip detection resistors having resistance values r1 to r4 are connected to the switches swS1 to sw4, respectively.

The resistance values r1 to r4 are set, for example, as follows.
“r1=4r”
“r2=2r=r1/2”
“r3=r=r1/4”
“r4=r/2 =r1/8”

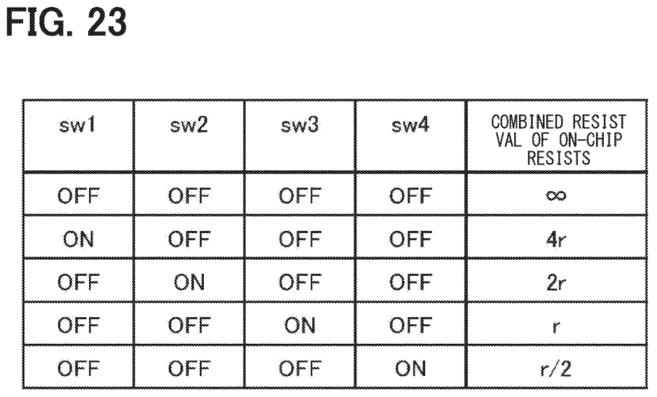

That is, the combined resistance value is set to a power of (½) of the reference resistance value r1, and the switches sw1 to sw4 are selectively turned on, thereby changing the combined resistance value as shown in FIG. 23. The resistance value may be changed by simultaneously turning on two or more switches, or the resistance value may be switched between infinity, r, r/2, and so on as in the first embodiment.

### Eleventh Embodiment

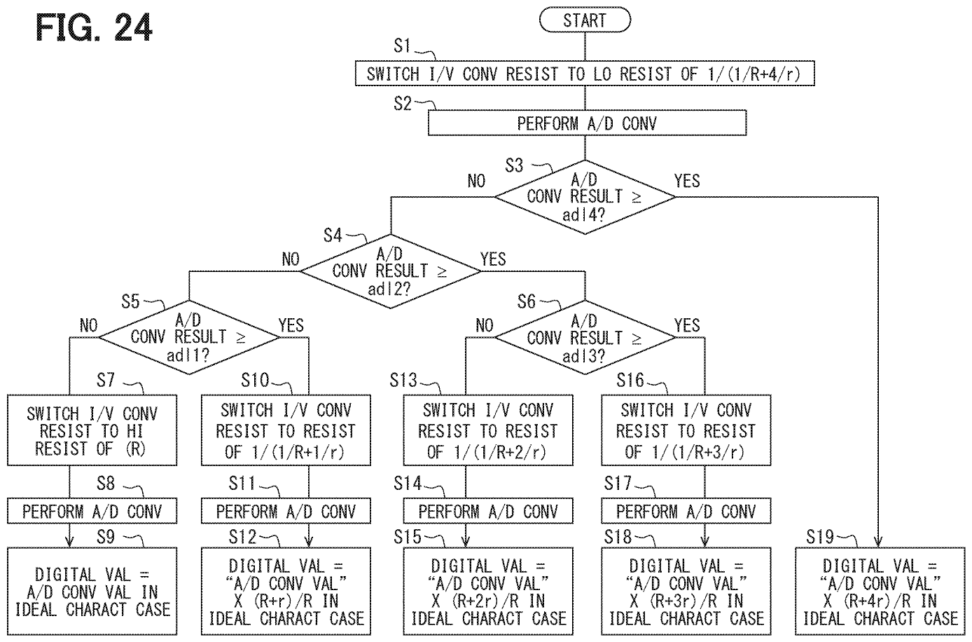

As shown in FIG. 24, the eleventh embodiment shows the control contents in the control unit 11. When the process starts, the combined resistance value for the I/V conversion is set to the lowest value of {1/(1/R+4/r)} (at S1), and the A/D conversion is performed (at S2). This process corresponds to the first data conversion. Then, the A/D conversion result is compared with each of the conversion values of adl4 to adl1 shown in FIG. 9 to determine whether or not it is equal to or greater than each of the conversion values of adl4 to adl1 (at S3 to S6).

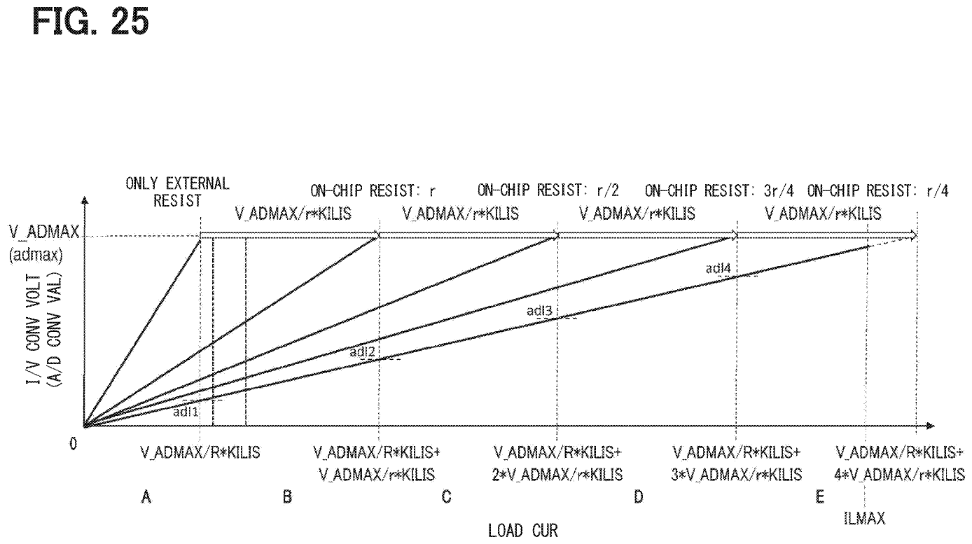

If the A/D conversion result is equal to or greater than the conversion value of adl4 (“YES” at S3), it belongs to the current region E shown in FIG. 25. In this case, the A/D conversion result is multiplied by a value of “(R+4r)/R” to obtain the final digital value according to the detected current (at S19). The above value of “(R+4r)/R” is the ratio of the combined resistance value of the off-chip detection resistor R and the four on-chip detection resistors r to the resistance value of the off-chip detection resistor R alone. Here, in the “ideal characteristic case” shown in the drawings, in order to simplify the explanation, the case where the conversion characteristic of the current output circuit 8 becomes nonlinear in the low current region is actually ignored.

If the A/D conversion result is less than the conversion value of adl1 (“NO” at S5), it belongs to the current region A, the on-chip detection resistor r is not connected, the resistor for the I/V conversion is switched to only the off-chip detection resistor R (at S7), and the A/D conversion is performed in the same manner as in step S2 (at S8). Then, the A/D conversion result is directly used as the final digital value (at S9). If the A/D conversion result is less than the conversion value of adl2 and greater than or equal to the conversion value of adl1 (“YES” at S5), it belongs to the current region B, and the resistance for the I/V conversion is switched to a parallel connection of an off-chip detection resistor R and one on-chip detection resistor r (at S10), and the A/D conversion is performed (at S11). In this case, the A/D conversion result is multiplied by a value of “(R+r)/R” to obtain the final digital value according to the detected current (at S12).

If the A/D conversion result is greater than or equal to the conversion value of adl2 and less than the conversion value of adl3 (“NO” at S6), it belongs to the current region C, and the resistance for the I/V conversion is switched to a parallel connection of the off-chip detection resistor R and two on-chip detection resistors r (at S13), and the A/D conversion is performed (at S14). In this case, the A/D conversion result is multiplied by a value of “(R+2r)/R” to obtain the final digital value according to the detected current (at S15).

If the A/D conversion result is less than the conversion value of adl4 and greater than or equal to the conversion value of adl4 (“YES” at S6), it belongs to the current region D, and the resistance for the I/V conversion is switched to a parallel connection of an off-chip detection resistor R and three on-chip detection resistors r (at S16), and the A/D conversion is performed (at S17). In this case, the A/D conversion result is multiplied by a value of “(R+3r)/R” to obtain the final digital value according to the detected current (at S18). Steps S8, S11, S14 and S17 correspond to a second data conversion. The conversion values adh1 to adh4 are stored in advance in a storage unit 11M (not shown) provided in the control unit 11.

As described above, according to the eleventh embodiment, the A/D conversion results adl1 to adl4 when the resistance value for the I/V conversion is set to the lowest value are stored in advance, and the actual A/D conversion results are compared with the A/D conversion results adl1 to adl4 to classify the cases into the current regions A to E. For the current regions A to D, the resistance for the I/V conversion is switched to a configuration in which the off-chip detection resistor R is used alone, or a configuration in which the on-chip detection resistor r of the resistance value change unit 16 is connected in parallel to the off-chip detection resistor R in sequence, and the A/D conversion is performed again. Thus, it is possible to virtually increase the conversion resolution in the current regions A to D by performing the A/D conversion a maximum of two times.

### Twelfth Embodiment

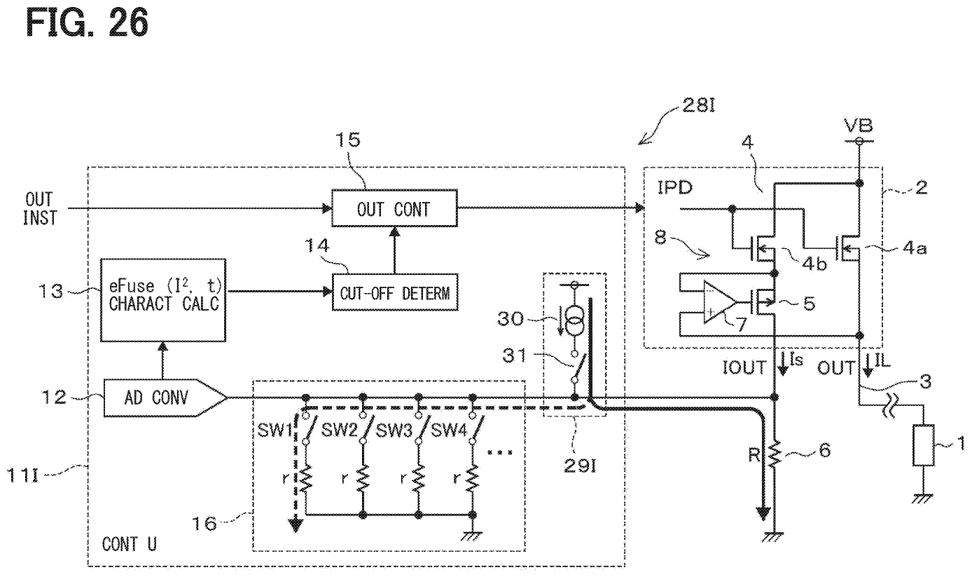

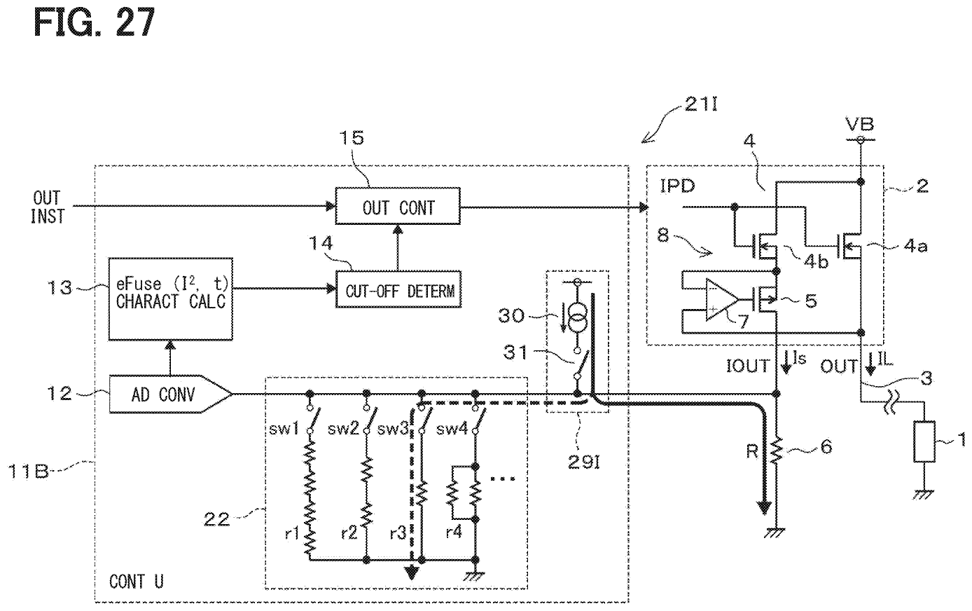

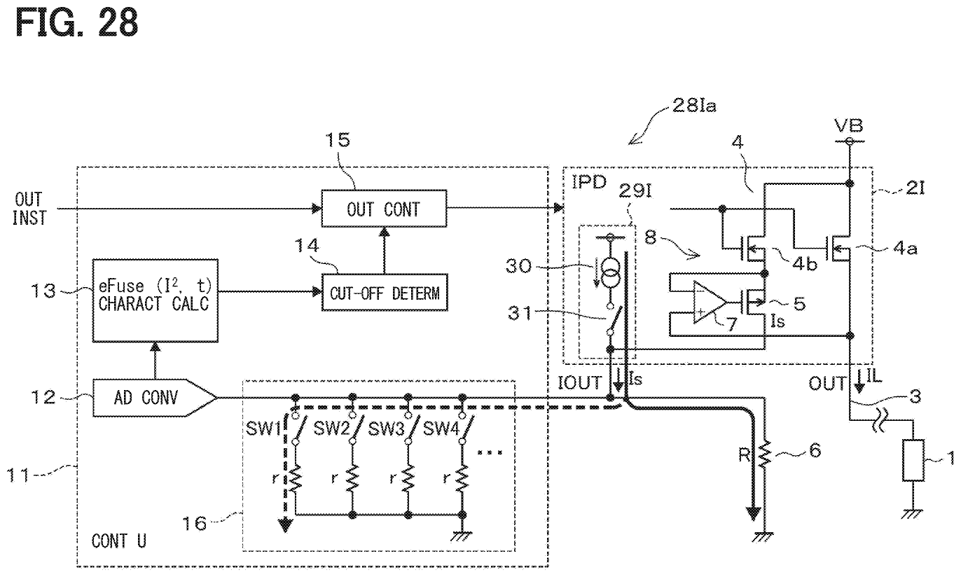

As shown in FIGS. 26 and 27, power supply devices 28I and 21I of the twelfth embodiment include a source-side current supply unit 29I in each of control units 11I and 11B. The control unit 11B includes the resistance value changing unit 22 of the tenth embodiment. The source side current supply unit 29I is configured with a series circuit of a current source 30 and a switch 31 connected between the power source VB and the ground. In addition, in a power supply device 28Ia shown in FIG. 28, a source-side current supply unit 29I is disposed inside the IPD 2I. The source side current supply unit 29I here is for diagnostics within the chip of the IPD2I.

In the configuration shown in FIGS. 26 and 27, when the load 1 is not energized from the IPD2, all of the on-chip detection resistors r are cut off, a current Itest is supplied from the source side current supply unit 29I to the off-chip detection resistor R, and the resulting voltage V_val1 is detected by the A/D converter 12. Similarly, when the load 1 is not energized from the IPD 2 and one or more on-chip detection resistors r are connected, a current is supplied from the source side current supply unit 29I to the I/V conversion resistor, and the resulting voltage V_val2 is detected by the A/D converter 12.

In the case of the configuration shown in FIG. 26, the voltage V_val1 generated when the switches S1 to S4 are all turned off is defined by an expression of “V_val1=R×Itest”. When only the switch S1 is turned on, the voltage is defined by an expression of “V_val2=1/(1/R+1/r)×Itest=R×r/(R+r)×Itest”.

In the case of the configuration shown in FIG. 27, the voltage V_val1 generated when the switches S1 to S4 are all turned off is defined by an expression of “V_val1=R×Itest”. When only the switch S4 is turned on, the voltage V_val2 generated is defined by an expression of “V_val2=1/(1/R+1/r4)×Itest=R×r4/(R+r4)×Itest”.

Here, the on-chip detection resistors r1 to r4 are resistors in the same semiconductor chip, and the resistance ratios of each can be considered to be constant. Therefore, if any of the resistance values is known, for example, the resistance values of each resistors can be determined from relational expressions such as “r1=4r”, “r2=2r”, “r3=r”, and “r4=r/2”.

In the configuration shown in FIG. 28, when the switches S1 to S4 are all turned off and the current Idiag is supplied from the source side current supply unit 29I while the load 1 is not energized from the IPD 2I, the generated voltage V_val1 is defined by an expression of “V_val1=R×Idiag”. From this expression, the voltage V_val2 generated when only the switch S1 is turned on is defined by an expression of “V_val2=1/(1/R+1/r)×Idiag=R×r/(R+r)×Idiag”.

The resistance values of the on-chip detection resistors r, r1 to r4 can be corrected based on the values of the voltages Vval1 and Vval2, respectively, with the value of the off-chip detection resistor R being used as a reference.

### Thirteenth Embodiment

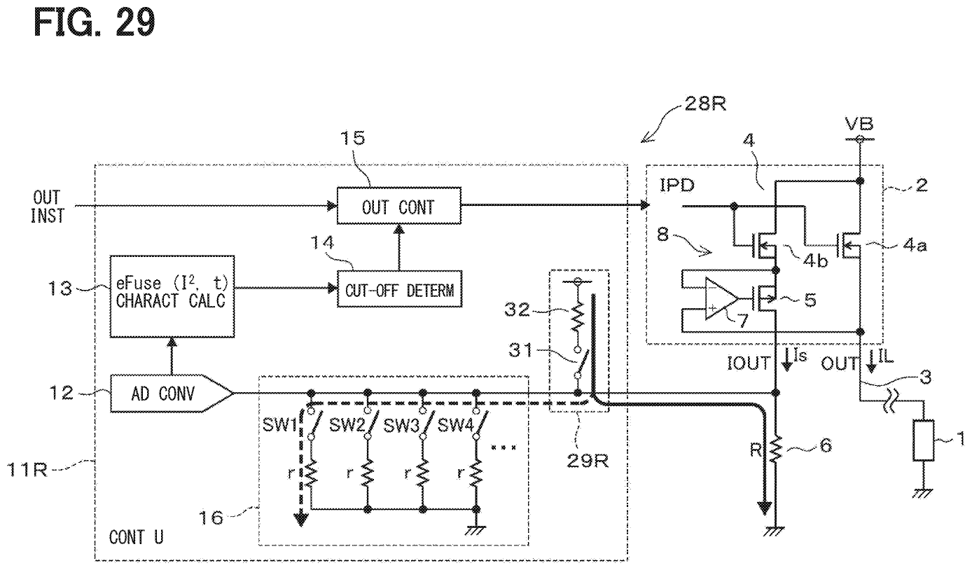

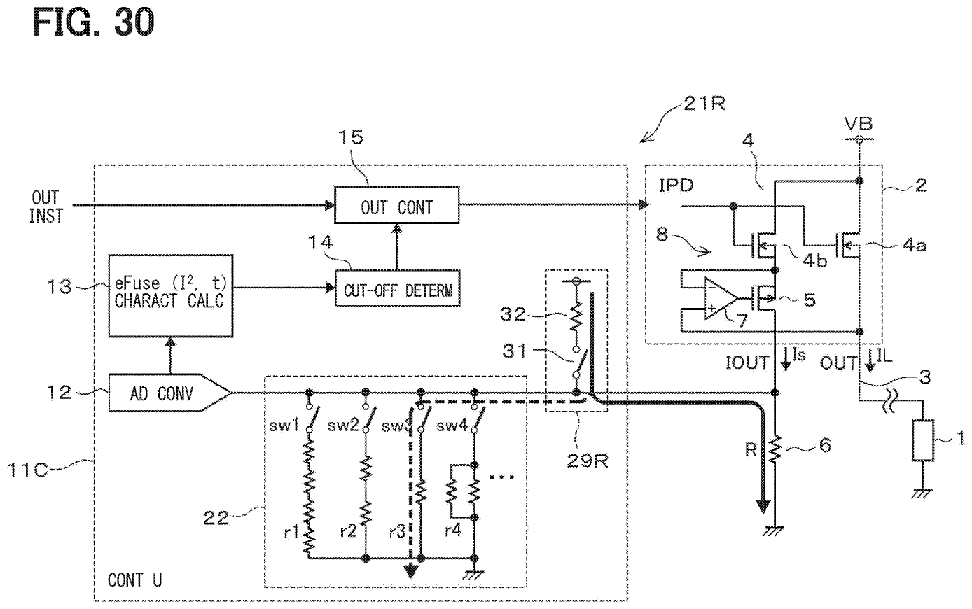

In power supply devices 28R and 21R of the thirteenth embodiment shown in FIGS. 29 and 30, the source side current supply unit 29I in the control units 11R and 11C is replaced with a source side current supply unit 29R. The source side current supply unit 29R includes a resistive element 32 having a resistance value Rtest instead of the current source 30.

In the case of the configuration shown in FIG. 29, when the switches S1 to S4 are all turned off and the switch 31 of the source side current supply unit 29R is turned on in a state in which the load 1 is not energized from the IPD 2, the generated voltage V_val1 is defined by an expression of “V_val1=VCC×R/(R+Rtest)”.

From this expression, the voltage V_val2 generated when only the switch S1 is turned on is defined by an expression of “V_val2=VCC×R×r/(Rtest×r+r×R+Rtest×R)”.

Here, since the resistor Rtest and the on-chip detection resistor r are resistors in the same semiconductor chip, the resistance ratio between them can be considered to be constant. If an expression of “r=Rtest×a” is established, an expression of “V_val1=VCC×R/(R+Rtest), and an expression of “V_val2=VCC×R×Rtest×a/(a×Rtest2+a×Rtest×R+Rtest×R)” are satisfied.

In the case of the configuration shown in FIG. 30, when the switches S1 to S4 are all turned off and the switch 31 of the source side current supply unit 29R is turned on in a state in which the load 1 is not energized from the IPD 2, the generated voltage V_val1 is defined by an expression of “V_val1=VCC×R/(R+Rtest)”.

From this expression, the voltage V_val2 generated when only the switch S3 is turned on is defined by an expression of “V_val2=VCC×R×r3/(Rtest×r3+r3×R+Rtest×R)”.

Here, the resistance ratio between the resistor Rtest and the on-chip detection resistors r1 to r4 can be considered to be constant, similarly to the above. If an expression of “r3=Rtest×a” is established, an expression of “V_val1=VCC×R/(R+Rtest) and an expression of “V_val2=VCC×R×Rtest×a/(a×Rtest2+a×Rtest×R+Rtest×R)” are satisfied.

Moreover, the resistance ratios of the on-chip detection resistors r1 to r4 can be considered to be constant. Therefore, if any of the resistance values is known, for example, the resistance values of each resistors can be determined from relational expressions such as “r1=4r”, “r2=2r”, “r3=r”, and “r4=r/2”.

Next, the operation of the thirteenth embodiment will be described. Incidentally, the same effect can be achieved in the configuration of the twelfth embodiment as well. As shown in FIG. 12, the process starts in a self-check mode with the output control unit 15 turning off the IPD 2 or controlling the IPD 2 in a standby mode. First, the switch 31 of the source side current supply unit 29I or 29R is turned on to pass a current through a resistor for I/V conversion, i.e., the off-chip detection resistor R (at S21). Then, the A/D conversion is performed by the A/D converter 12, and the resistance value that can be read from the conversion result is determined (at S22). Here, a comparator may be used for the determination.

If the determined resistance value is equal to or greater than the upper threshold value (“YES” at S23), there is a possibility that the connection of the I/V conversion resistor is open or shorted to the power supply, and therefore it is determined that an anomaly has occurred (at S28). Then, for example, an instruction to execute a diagnosis is transmitted to a higher-level control device or the IPD 2 is maintained in the off state (at S29).

If the determined resistance value is equal to or less than the lower threshold value (“YES” at S24), there is a possibility that the connection of the I/V conversion resistor has a ground fault, and therefore it is determined that an anomaly has occurred (at S26). Then, a process similar to that in step S29 is performed (at S27). On the other hand, if the determined resistance value is above the lower threshold value (“NO” at S24), it is determined to be normal (at S25).

As described above, according to the twelfth or thirteenth embodiment, in a state where the IPD 2 stops energizing the load 1, the resistance values of the on-chip detection resistors r and r1 to r4 are corrected in accordance with the data value converted when the source side current supply unit 29I or the like energizes the off-chip detection resistor R. In addition, by determining the resistance value when a source current is passed through the I/V conversion resistor via the source side current supply unit 29 while the IPD2 is turned off, for example, it is possible to determine whether the connection of the I/V conversion resistor is in a normal state or in an anomaly state. Furthermore, if the resistance value of the off-chip detection resistor is configured to be switchable, the anomaly on only the high resistance side can also be detected by comparing the A/D conversion results on the low resistance side and the high resistance side after starting the energization. Therefore, at the very least, it is necessary to detect the presence or absence of an anomaly on the low resistance side before performing the above-described process. It may be also desirable to determine whether the resistance value on the high resistance side after switching is in a normal state or not, and to perform similar process if an anomaly is detected.

### Fourteenth Embodiment

As shown in FIGS. 13 and 14, in the fourteenth embodiment, in the control unit 11I, 11R, 11B or 11C of the twelfth or thirteenth embodiment, the type of IPD 2 connected is determined based on the resistance value of the off-chip detection resistor R. As shown in FIG. 13, when process is started in a self-check mode in the same manner as in the fourth embodiment, the process similar to step S21 is performed (at S31). Then, the A/D conversion is performed by the A/D converter 12, and the conversion result is obtained as resistance value data ValR (at S32). The control parameters are set based on the resistance value data ValR (at S33).

The control unit 11I stores a data table for determining the type of the IPD 2, for example, as shown in FIG. 14. For example, if the resistance value R is in the range of 5 kΩ to 7.5 kΩ, the type of the IPD 2 is defined as “KILIS=500”, and the wire cross-sectional area of the harness 3 is 0.15 mm². For example, if the resistance value R is in the range of 10 kΩ to 12.5 kΩ, the type of the IPD 2 is defined as “KILIS=1000”, and the wire cross-sectional area of the harness 3 is 0.3 mm². These are set as parameters used in eFuse control. This information can also be used to enable the control to be started with rough parameters before obtaining information such as accurate conversion ratios and correction values from a higher level microcomputer, for example.

By making it possible to switch the combination of connections with the on-chip detection resistor, there is no difficulty even if the resistance value of the off-chip detection resistor is high. Therefore, parameter setting and current monitoring can be achieved with one terminal, so that it is not necessary to provide a terminal that has conventionally been provided for setting parameters. Thus, it is possible to reduce the number of terminals and components such as resistors dedicated to parameter setting.

### Fifteenth Embodiment

As shown in FIG. 15, in the fifteenth embodiment, the quality of the connection of the off-chip detection resistor R is determined in the same manner as in the twelfth embodiment and the like. After steps S26 and S28 have been executed, for example, when performing correction on the A/D conversion result using a linear function, Bh shown in FIG. 16 as an offset parameter, i.e., an intercept, is changed to a value larger than the value normally used (at S42). Here, the functional part that performs the correction using the linear function corresponds to the correction unit.

Thereafter, when the IPD 2 starts energizing, it is possible to recognize using the correction value of the A/D conversion result that a large current is flowing regardless of the actual load current IL. As a result, by the eFuse control function or the power amount monitoring function, the protection to cut off the current is activated in a short time, so that the load 1 can be safely protected. If the determination at step S24 is “No,” the source-side current supply source 29 is turned off and eFuse control and the like are started.

### Sixteenth Embodiment

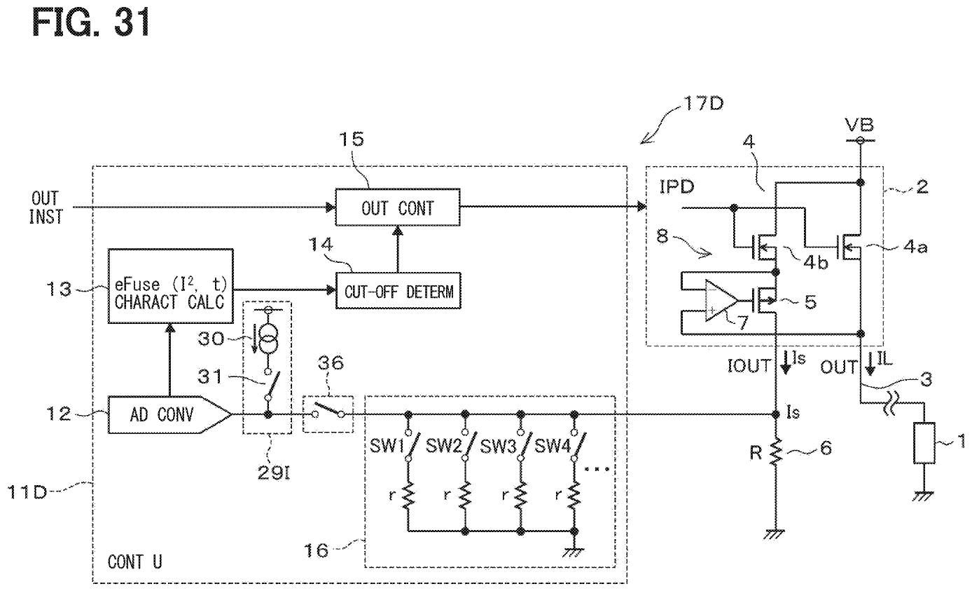

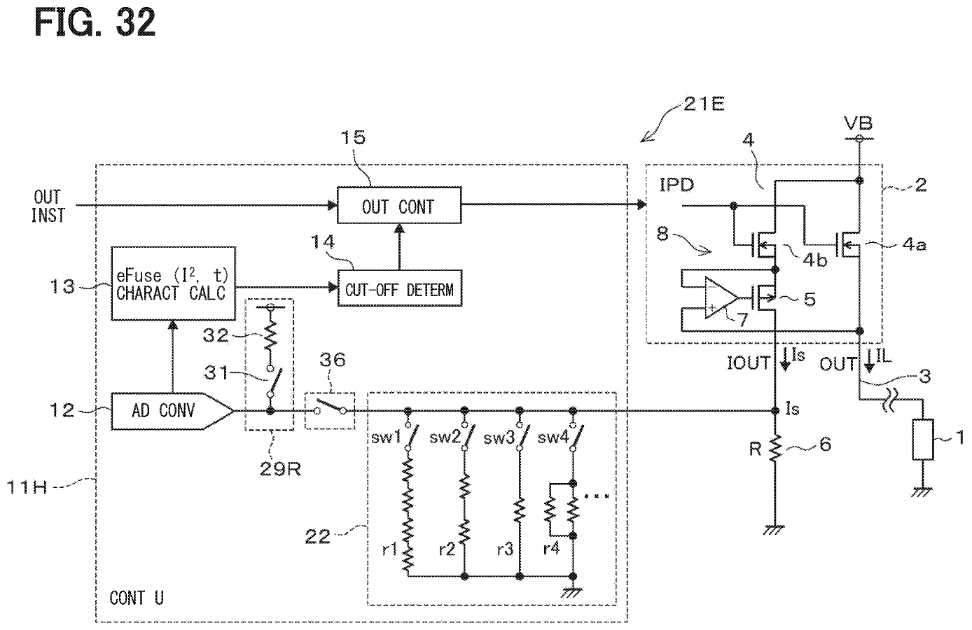

The sixteenth embodiment is a modification of the fifteenth embodiment. As shown in FIG. 31, a normally-closed switch 36 is inserted between the input terminal of the A/D converter 12 and the resistance value changing unit 16, and the source side current supply unit 29I of the sixth embodiment is connected to the common connection point between the input terminal and the switch 36. FIG. 32 shows a configuration of a control unit 11H obtained by connecting a switch 36 and a source-side current supply source 29R to the same positions as in FIG. 31 in the control unit 11C having the resistance value changing unit 22 shown in FIG. 30.

In the flow chart shown in FIG. 18, step S42 is replaced with step S43. In step S43, the switch 36 is turned off, and the switch 31 of the source side current supply unit 29I or 29R is turned on. As a result, when the IPD 2 starts energizing, the voltage input to the A/D converter 12 becomes higher than the normal input range, so that it is recognized that a large current is flowing regardless of the actual load current IL. As a result, by the eFuse control function or the power amount monitoring function, the protection to cut off the current is activated in a short time, so that the load 1 can be safely protected.

### Other Embodiments

The resistance value of the off-chip detection resistor may be changed in three or more stages. Moreover, it is not always necessary to change the resistance value.

The number of current sources provided in the sink side current source unit may be “3” or less, or “5” or more.

Moreover, the A/D converter 12 and the eFuse (I², t) characteristic calculation unit 13 may be integrated to configure a data converter that outputs a conversion result according to the characteristic of the squared current.

The present embodiments include the following features.

Feature 1: A power supply device includes: a power device that supplies current from a driving power source to a load; an off-chip detection resistor through which another current based on the current is energized; a data converter that converts a voltage converted by the off-chip detection resistor into a data value based on a predetermined characteristic; a protection operation unit that performs a protection operation to stop the power device from supplying the current to the load when a calculation value based on the data value exceeds a threshold value; and an IC chip on which the data converter and the protection operation unit are mounted. The IC chip has a configuration capable of switching a voltage level obtained with respect to another current based on the current in a plurality of stages.

Feature 2: The power supply device according to feature 1, further includes: gain switching unit that switches the voltage level obtained by switching a gain with respect to another current based on the current. The data converter performs data conversion with the gain set to a minimum value, and the gain for detecting the current is determined according to a converted data value.

Feature 3: The power supply device according to feature 1 or 2, further includes: a source-side current supply source that energizes the off-chip detection resistor in a state where the power device stops energizing the load. An anomaly in a connection state of the off-chip detection resistor is determined in accordance with a data value converted when energizing.

Feature 4: The power supply device according to feature 3, further includes: correction unit that corrects an output data of the data converter. When an anomaly of the detection resistor is detected, a correction parameter of the correction unit is set so that the protection operation unit starts performing the protection operation more quickly.

Feature 5: In the power supply device according to feature 3, when an anomaly of the detection resistor is detected, an input voltage of the data converter is set to be higher than a normal input range.

Feature 6: The power supply device according to any one of features 1 to 5, further includes: a source-side current supply source that energizes the off-chip detection resistor in a state where the power device stops energizing the load. The control unit determines a resistance value of the off-chip detection resistor based on a result of data conversion associated with energization, and sets a control parameter according to a determined resistance value.

Feature 7: In the power supply device according to any one of features 1 to 6, the IC chip includes a resistance value changing unit that has a plurality of on-chip detection resistors connectable in parallel to the off-chip detection resistor. The data converter performs data conversion in a state where a combined resistance value of the off-chip detection resistor and the on-chip detection resistor is in a minimum state, the combined resistance value for detecting the current is determined according to a converted data value.

Feature 8: The power supply device according to any one of features 1 to 7, further includes: a source-side current supply unit that energizes the off-chip detection resistor in a state where the power device stops energizing the load. The resistance value of the on-chip detection resistor is corrected according to a data value converted when the off-chip detection resistor is energized by the source side current unit.

Feature 9: The power supply device according to feature 8, further includes: correction unit that corrects an output data of the data converter. When an anomaly of the detection resistor is detected, a correction parameter of the correction unit is set so that the protection operation unit starts performing the protection operation more quickly.

Feature 10: In the power supply device according to feature 8, when an anomaly of the detection resistor is detected, an input voltage of the data converter is set to be higher than a normal input range.

Although the present disclosure has been made in accordance with the embodiments, it is understood that the present disclosure is not limited to such embodiments and structures. The present disclosure includes various modifications or deformations within an equivalent range. Furthermore, various combination and formation, and other combination and formation including one, more than one or less than one element may be made within the spirit and scope of the present disclosure.

It is noted that a flowchart or the processing of the flowchart in the present application includes sections (also referred to as steps), each of which is represented, for instance, as S51. Further, each section can be divided into several sub-sections while several sections can be combined into a single section. Furthermore, each of thus configured sections can be also referred to as a device, module, or means.

While the present disclosure has been described with reference to embodiments thereof, it is to be understood that the disclosure is not limited to the embodiments and constructions. The present disclosure is intended to cover various modification and equivalent arrangements. In addition, while the various combinations and configurations, other combinations and configurations, including more, less or only a single element, are also within the spirit and scope of the present disclosure.

What is claimed is:

1. A power supply device comprising:
a power device that supplies current from a driving power source to a load;
a detection resistor through which another current based on the current is energized;
a data converter that converts a voltage generated by the detection resistor into a data value as a first data conversion based on a predetermined characteristic;
a cut-off determination unit together with a calculator for controlling an e-fuse that determine a cut-off based on the data and a characteristic corresponding to a square of the current; and
an IC chip on which the data converter and the calculator for controlling the e-fuse are mounted, wherein:
the IC chip has a configuration capable of switching a voltage level obtained with respect to another current based on the current in a plurality of stages.

2. The power supply device according to claim 1, further comprising:
a gain switching unit that switches the voltage level obtained by switching a gain with respect to another current based on the current, wherein:
the data converter performs a second data conversion in a state where the gain is set to a minimum value; and
the gain for detecting the current is determined according to a converted data value.

3. The power supply device according to claim 2, wherein:
the current is detected based on a result of the first data conversion in response that the result of the first data conversion is disposed in a predetermined range.

4. The power supply device according to claim 2, wherein:
the gain switching unit switches the gain from a minimum gain as a first gain to a maximum gain as a second gain in response that a result of the first data conversion is smaller than a first threshold.

5. The power supply device according to claim 2, wherein:
the gain switching unit switches the gain to a third gain which is higher than a minimum gain as a first gain and lower than a maximum gain as a second gain in response that a result of the first data conversion is equal to or larger than a first threshold and smaller than a second threshold.

6. The power supply device according to claim 4, wherein:
the second gain is four times larger than the first gain.

7. The power supply device according to claim 5, wherein:
the third gain is twice larger than the first gain.

8. The power supply device according to claim 2, wherein:
the gain includes a predetermined gain, twice the predetermined gain, and four times the predetermined gain.

9. The power supply device according to claim 2, wherein:
The gain switching unit switches the gain using a plurality of switches.

10. The power supply device according to claim 2, wherein:
the gain switching unit sets a minimum gain so as to set an input voltage of the data converter to be equal to or smaller than a maximum input voltage even in case of a maximum load current.

11. The power supply device according to claim 2, wherein:
the gain is selected to maximize a resolution of the data conversion within an allowable input voltage range of the data converter.

12. The power supply device according to claim 2, wherein:
the detecting of the current is executed by the first and second data conversions at most twice.

13. The power supply device according to claim 2, wherein:
the gain switching unit sets the gain to be slightly higher than a standard gain ratio as the gain becomes smaller.

14. A current detection method for a power supply device that supplies current from a driving power source to a load, the current detection method comprising:
a step for generating another current based on the current to a voltage;
a first data conversion step for converting the voltage to data in a state where a minimum gain is set among a plurality of gains; and
a step for determining a gain for detecting the current based on the data obtained in the first data conversion step.

15. The current detection method according to claim 14, further comprising:
a second data conversion step for converting the voltage to data after switching the gain determined in the determining of the gain.

16. The current detection method according to claim 14, further comprising:
a step for determining a current range according to a result of the first data conversion step.

17. The current detection method according to claim 14, wherein:
the detecting of the current is executed by the data conversion at most twice.

18. The current detection method according to claim 14, wherein:
in the step for determining the gain, the gain is selected so as to increase a resolution of the data conversion to be higher than a predetermined resolution within an allowable input voltage range of the data conversion.
